(19) United States
(12) Patent Application Publication
(10) Pub. No.: US 2020/0071024 A1
(43) Pub. Date: Mar. 5, 2020

(54) PACKAGING DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: ZHAO-QIANG HE, Shenzhen (CN); CHENG-FA CHUNG, New Taipei (TW)

(21) Appl. No.: 16/186,315

(22) Filed: Nov. 9, 2018

(30) Foreign Application Priority Data
Aug. 28, 2018 (CN) 201810986019.6

(51) Int. Cl. B65D 25/04; B65D 81/02; B65D 85/30; H01L 21/673

(52) U.S. Cl. CPC B65D 25/04; H01L 21/6734; B65D 85/30; B65D 81/022

(57) ABSTRACT

A device used in manufacturing for transportation of workpieces of different sizes includes a supporting part, the supporting part including a support plate and parallel and detachable separator plates mounted to the support plate. The support plate includes bottom, first side plate, second side plate, and connecting plate. First and second side plates are parallel and opposing, the connecting plate is connected therebetween. Each separator plate includes a main portion and a protruding first limiting portion. The first limiting portion of one separator plate abuts against the first side plate, and each first limiting portion of other separator plates abuts against the main portion of a neighboring separator plate. The gaps formed between the main portions of neighboring separator plates carry the workpieces being transported.

### FIELD

The disclosure generally relates to packaging devices used during manufacture.

### BACKGROUND

In production process of electronic devices such as liquid crystal displays, it is necessary to transport the electronic devices between different procedures. A handling or packaging device is used to protect the electronic devices from being damaged during transporting process. A conventional packaging device includes an upper supporting plate and a lower supporting plate opposing the upper supporting plate. The lower supporting plate includes a plurality of separator plates, and the electronic devices are separated by the separator plates that are fixed between the upper supporting plate and the lower supporting plate. The packaging device can accommodate an electronic device of a predetermined size.

### BRIEF DESCRIPTION OF THE DRAWINGS

Many aspects of the present disclosure can be better understood with reference to the drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an isometric view of an embodiment of a packaging device.

FIG. 2 is an exploded isometric view of a supporting part of the packaging device of FIG. 1.

FIG. 3 is an isometric view of a support plate of the supporting part shown in FIG. 2.

FIG. 4 is similar to FIG. 3 viewed from another angle.

FIG. 5 is an isometric view of an insert piece of the supporting part of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as coupled, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like.

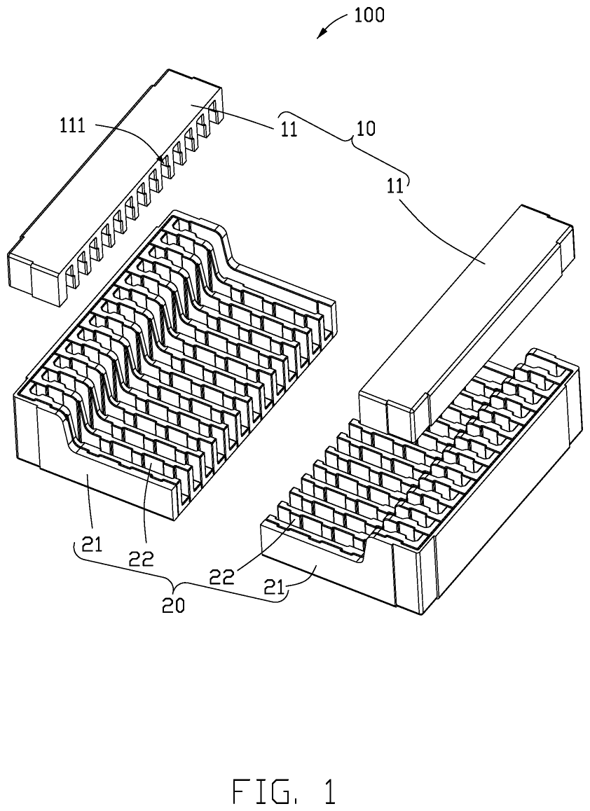

FIG. 1 shows an embodiment of a packaging device (handling device) 100 used during manufacture, according to the present disclosure. The packaging device 100 can include a covering part 10 and a supporting part 20. In at least one embodiment, the covering part 10 and the supporting part 20 can be made of polystyrene.

The covering part 10 can include two cover plates 11 spaced apart from each other. Each cover plate 11 can be substantially rectangular, and one side of each cover plate 11 facing toward the supporting part 20 includes a plurality of receiving grooves 111. The plurality of receiving grooves 111 can be arranged at equal spacing from one another, and each receiving groove 111 can be substantially rectangular.

The supporting part 20 can include two support plates 21 spaced apart from each other. Each support plate 21 can be arranged to correspond to one of the cover plates 11. The supporting part 20 can further include a plurality of separator plates 22 detachably mounted on each support plate 21. The plurality of separator plates 22 on each support plate 21 can be parallel to each other and connected in singles in parallel.

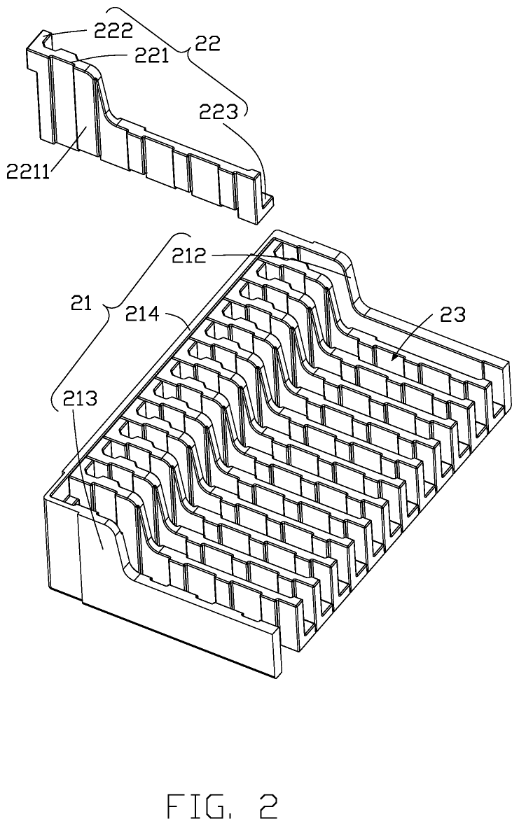

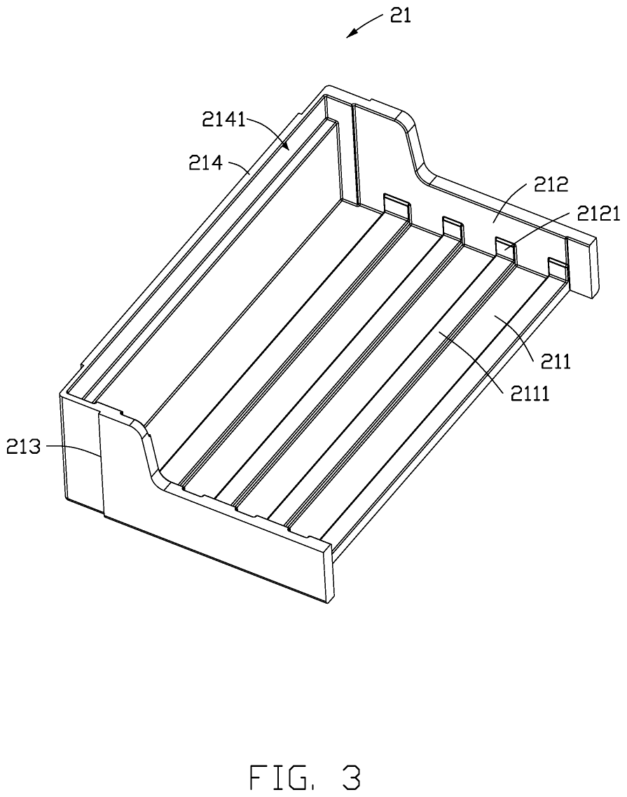

FIG. 2 and FIG. 3 show that the support plate 21 can include a bottom plate 211, and a first side plate 212, a second side plate 213, and a connecting plate 214 perpendicularly connected to the bottom plate 212. The first side plate 212 can be parallel to and opposing the second side plate 213. The connecting plate 214 can be connected between the first side plate 212 and the second side plate 213. In at least one embodiment, the bottom plate, the first side plate 212, the second side plate 213, and the connecting plate 214 can be integrally formed.

A surface of the bottom plate 211 toward the cover plate 11 can include at least one flange rib 2111. Each flange rib 2111 can be substantially strip-shaped. One end of each flange rib 2111 can extend to the first side plate 212 and another end of each flange rib 2111 can extend to the second side plate 213. In at least one embodiment, the bottom plate 211 can include four flange ribs 2111. In other embodiments, the bottom plate 211 can include one or more flange ribs 2111.

The first side plate 212 can include at least one protrusion block 2121 at a side surface toward the separate plates 22, and the at least one protrusion block 2121 can be connected to the at least one flange rib 2111. In at least one embodiment, the first side plate 212 can include four protrusion blocks 2121, and the four protrusion blocks 2121 can be arranged to correspond to the flange ribs 2111. In other embodiments, the side plate 212 can include one or more protrusions 2121.

A top surface of the connecting plate 214 away from the bottom plate 211 can define a concave portion 2141. The concave portion 2141 can be substantially strip-shaped and parallel to the flange rib 2111. One end of the concave portion 2141 can extend to the first side plate 212, and another end of the concave portion 2141 can extend to the second side plate 213, thereby the top surface of the connecting plate 214 is stepped.

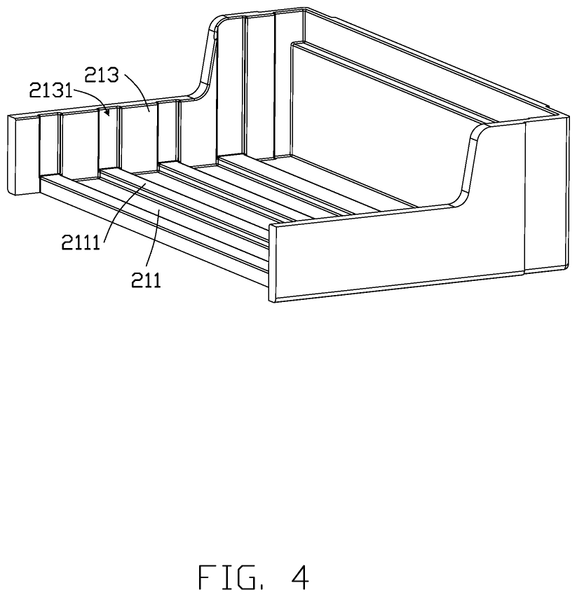

FIG. 4 shows that a surface of the second side plate 213 toward the separator plate 22 can define at least one groove 2131. The at least one groove 2131 can be strip-shaped and perpendicular to the bottom plate 211, and the at least one groove 2131 can be arranged to correspond with one end of the flange rib 2111. In at least one embodiment, the second side plate 212 can include four parallel grooves 2131. In other embodiments, the second side plate 212 can include one or more grooves 2131.

FIG. 4 shows that the separator plate 22 can include a main portion 221, a first limiting portion 222, and a second limiting portion 223. The first limiting portion 222 and the second limiting portion 223 can be protruding from two ends of the main portion 221.

The main portion 221 can be a flat plate. The main portion 221 can comprise at least one protrusion portion 2211 on a surface of the main portion 221 toward the first side plate 212. A surface of the main portion 221 toward the second side plate 213 can include at least one protrusion portion 2211. The at least one protrusion portion 2211 can be strip-shaped and perpendicular to the bottom plate 211. The protrusion portion 2211 on the separator plate 22 adjacent to the second side plate 213 can engage with the groove 2131 of the second side plate 213. The at least one protrusion portion 2211 on other separator plates 22 can be in contact with the electronic device. In at least one embodiment, each separator plate 22 includes a plurality of protrusion portions 2211 which are parallel to and spaced from each other.

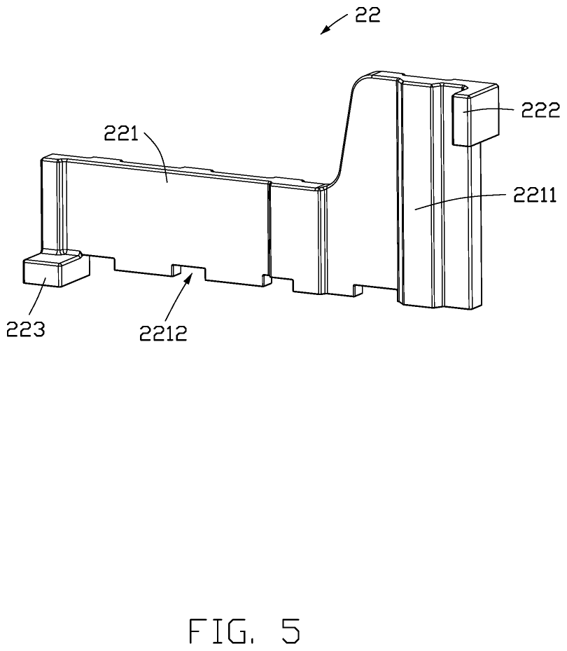

FIG. 2, FIG. 3, and FIG. 5 show that one surface of the main portion 221 toward the bottom plate 211 can define a positioning groove 2212. The positioning groove 2212 can engage with the flange rib 2111, thereby the separator plate 22 can be connected to the bottom plate 211. In at least one embodiment, each separator plate 22 can include a plurality of positioning grooves 2212, and the plurality of positioning grooves 2212 can engage with the plurality of the flange ribs 2211.

The first limiting portion 222 and the second limiting portion 223 can be formed at one surface of the main portion 221 facing toward the first side plate 212. The first limiting portion 222 can be arranged at an edge of the main portion 221 and perpendicular to the main portion 221. In at least one embodiment, the first limiting portion 222 can be arranged at one end the main portion 221 positioned away from the bottom plate 211, and the first limiting portion 222 can be connected to the connecting plate 214. The first limiting portion 222 can engage with the concave portion 2141 of the connecting plate 214.

The first limiting portion 222 of one separator plate 22 abuts against the first side plate 212, and each first limiting portion 222 of other separator plates 22 abuts against the main portion 221 of a neighboring separator plate 22. Gaps 23 are thereby formed between the main portions 221 of neighboring separator plates 22, each gap 23 is configured for receiving one electronic device.

The second limiting portion 223 can be arranged at one end of the main portion 221 away from the connecting plate 214, and the second limiting portion 223 can be positioned on the bottom plate 211. A length of the first limiting portion 222 and a length of the second limiting portion 223 along an extending direction of the connecting plate are equal, thereby the gaps 23 formed between the main portions 221 of neighboring separator plates 22 can be equal.

When being used, a plurality of electronic devices can be placed on the supporting part 20, the ends of each electronic device are on the two support plates 21. One electronic device is placed between the first side plate 212 and the separator plate 22 adjacent to the first side plate 212. Other electronic devices can be placed in the gaps 23 between neighboring separator plates 22. The covering part 10 covers the supporting part 20, thus the packaging device 100 cradles and protects the electronic devices. The packaging device 100 with the electric devices can be housed inside a box or other support for improving the stability of the packaging device 100. The packaging device 100 can buffer the electronic devices against impact and damage in the transporting process.

In addition, as the separator plates 22 are detachably connected to the bottom plate 21, the separator plates 22 are easily removed. Therefore, when size of the electronic devices changes, the separator plates 22 can be replaced to accommodate electronic devices of different sizes. The bottom plate 21 is able to accommodate different sizes of the electronic devices, so there is no need to develop new dies for the bottom plate, and the manufacturing cost of the packaging device 100 can be saved.

In other embodiments, the covering part 10 can include one cover plate 11, and the supporting part 20 can include one support plate 21. In other embodiments, the covering part 10 can be omitted.

In other embodiments, the separator plate 22 can include one of the first limiting portion 222 and the second limiting portion 223, as long as the gaps 223 are maintained between neighboring separator plates 22.

In other embodiments, the flange rib 2111 of the bottom plate 211 can be replaced with a positioning groove. Accordingly, the main portion 221 of the separator plate 22 can include a rib, as long as the separator plate 22 can be connected to the bottom plate 211.

In other embodiments, the protrusion portions 2211 can be omitted, and the main portion 221 can be in contact with the electronic device.

In other embodiments, the packaging device 100 can be made of paper, elastic, or other materials.

It is to be understood, however, that even through numerous characteristics and advantages of the present disclosure have been set fourth in the foregoing description, together with details of assembly and function, the disclosure is illustrative only, and changes may be made in details, especially in the matters of shape, size, and arrangement of parts within the principles of the disclosure to the full extent indicated by the broad general meaning of the terms in which the appended claims are expressed.

What is claimed is:

1. A packaging device configured for packaging a plurality of electronic devices, comprising a supporting part, the supporting part comprises:
a support plate comprising a bottom plate, and a first side plate, a second side plate, and a connecting plate perpendicular to the bottom plate, the first side plate being parallel to and opposing the second side plate, and the connecting plate being connected between the first side plate and the second side plate; and
a plurality of separator plates detachably mounted to the support plate and parallel to each other;
wherein each separator plate comprises a main portion and a first limiting portion protruding from one end of the main portion, the first limiting portion of one separator plate abuts against the first side plate, and each first limiting portion of other separator plates abuts against the main portion of a neighboring separator plate, thereby gaps are formed between the main portions of neighboring separator plates, and each gap is configured for receiving one electronic device.

2. The packaging device of claim 1, wherein the bottom plate comprises a flange rib, one end of the flange rib extends to the first side plate, and another end of the flange rib extends to the second side plate; the main portion of separator plate facing toward the bottom plate comprises a positioning groove, and the positioning groove engages with the flange rib.

3. The packaging device of claim 1, wherein the first limiting portion is arranged at one end the main portion positioned away from the bottom plate, and the first limiting portion is connected to the connecting plate.

4. The packaging device of claim 3, wherein a top surface of the connecting plate away from the bottom plate defines a concave portion, one end of the concave portion extends to the first side plate, another end of the concave portion extends to the second side plate, and the first limiting portion engages with the concave portion.

5. The packaging device of claim 4, wherein the separator plate further comprises a second limiting portion protruding from the main portion, the second limiting portion is arranged at one end of the main portion away from the connecting plate and positioned on the bottom plate, a length of the first limiting portion and a length of the second limiting portion along an extending direction of the connecting plate are equal, and the gaps between the main portions of each two neighboring separator plates are equal.

6. The packaging device of claim 1, wherein a surface of the main portion toward the second side plate comprise at least one protrusion portions, and the at least one protrusion portion is stripped shaped and perpendicular to the bottom plate.

7. The packaging device of claim 6, wherein a surface of the second side plate toward the separator plate defines at least one groove, the at least one protrusion portion on the separator plate adjacent to the second side plate engages with the at least one groove of the second side plate.

8. The packaging device of claim 1, wherein the packaging device further comprises a covering part, the covering part comprises a cover plate, one side of the cover plate facing toward the supporting part defines a plurality of receiving grooves, and the plurality of receiving grooves is arranged at equal spacing from one another.

9. The packaging device of claim 8, wherein the covering part comprises two cover plates spaced from each other, the supporting part comprises two support plates spaced from each other, the two cover plates are arranged corresponding to the two supporting parts.

10. The packaging device of claim 8, wherein the covering part and the supporting part are made of polystyrene.

11. The packaging device of claim 1, wherein the bottom plate, the first side plate, the second side plate, and the connecting plate are integrally formed.

12. A packaging device configured for packaging a plurality of electronic devices, comprising:
a covering part, comprising two cover plates spaced from each other; and
a supporting part, comprising:
two support plates spaced from each other, each support plate comprising a bottom plate, and a first side plate, a second side plate, and a connecting plate perpendicular to the bottom plate, the first side plate being parallel to and opposing the second side plate, and the connecting plate being connected between the first side plate and the second side plate; and
a plurality of separator plates detachably mounted to the two support plates and parallel to each other;
wherein each separator plate comprises a main portion and a first limiting portion protruding from one end of the main portion, the first limiting portion of one separator plate abuts against the first side plate, and each first limiting portion of other separator plates abuts against the main portion of a neighboring separator plate, thereby gaps are formed between the main portions of neighboring separator plates, and each gap is configured for receiving one electronic device.

13. The packaging device of claim 12, wherein the bottom plate comprises a flange rib, one end of the flange rib extends to the first side plate, and another end of the flange rib extends to the second side plate; the main portion of separator plate facing toward the bottom plate defines a positioning groove, and the positioning groove engages with the flange rib.

14. The packaging device of claim 12, wherein the first limiting portion is arranged at one end the main portion away from the bottom plate, and the first limiting portion is connected to the connecting plate.

15. The packaging device of claim 14, wherein a top surface of the connecting plate away from the bottom plate defines a concave portion, one end of the concave portion extends to the first side plate, another end of the concave portion extends to the second side plate, and the first limiting portion engages with the concave portion.

16. The packaging device of claim 15, wherein the separator plate further comprises a second limiting portion protruding from the main portion, the second limiting portion is arranged at one end of the main portion away from the connecting plate and positioned the bottom plate, a length of the first limiting portion and a length of the second limiting portion along an extending direction of the connecting plate are equal, and the gaps between the main portions of each two neighboring separator plates are equal.

17. The packaging device of claim 12, wherein a surface of the main portion toward the second side plate comprise at least one protrusion portions, and the at least one protrusion portion is stripped shaped and perpendicular to the bottom plate.

18. The packaging device of claim 17, wherein a surface of the second side plate toward the separator plate defines at least one groove, the at least one protrusion portion on the separator plate adjacent to the second side plate engages with the at least one groove of the second side plate.

19. The packaging device of claim 12, wherein the covering part and the supporting part are made of polystyrene.

20. The packaging device of claim 12, wherein the bottom plate, the first side plate, the second side plate, and the connecting plate are integrally formed.
